(19) United States
(12) Patent Application Publication
(10) Pub. No.: US 2024/0322515 A1
(43) Pub. Date: Sep. 26, 2024

(54) COATED OPTICAL CRYSTALS AND METHODS FOR PRODUCING THE SAME

(71) Applicant: Gooch & Housego PLC, Ilminster (GB)

(72) Inventors: Lars SANDSTRÖM, Philadelphia, PA (US); Thomas STENGER, Willoughby, OH (US)

(21) Appl. No.: 18/615,023

(22) Filed: Mar. 25, 2024

Related U.S. Application Data
(60) Provisional application No. 63/454,392, filed on Mar. 24, 2023.

(51) Int. Cl. H01S 3/06; G02B 1/08; G02B 1/18; H01S 3/1123

(52) U.S. Cl. CPC H01S 3/0619; G02B 1/08; G02B 1/18; H01S 3/1123

(57) ABSTRACT

Provided is an optical apparatus comprising a hygroscopic optical crystal and a coating on at least a portion of the surface of the hygroscopic optical crystal, wherein the coating is non-porous and configured to prevent migration of water and/or oxygen and/or moisture therethrough.

### CROSS-REFERENCE TO RELATED APPLICATION

This present application claims the benefit and priority of U.S. Provisional Application No. 63/454,392 filed Mar. 24, 2023, the disclosure of which is hereby incorporated by reference in its entirety.

### TECHNICAL FIELD

This disclosure relates to coated optical crystals, and in particular to coated optical crystals for use, for example, in lasers such as cosmetic lasers. This disclosure also relates to methods for coating optical crystals and optical crystals coated using such methods.

### BACKGROUND

Optical crystals have a number of applications, for example as non-linear crystals in laser applications e.g. as frequency converters. They may also be used in the field of electro-optics, electro-optic modulators using the Pockels effect or the Kerr effect. Some crystals are sometimes used for their bi-refringence, e.g., as waveplates.

Over time, some optical crystals may become less effective due to environmental exposure. For example, the presence of moisture in the environment surrounding the crystal can cause a reaction with the surface of the crystal, which can affect the crystal's surface structure and/or surface composition. This in turn can affect the transmission, reflectance and/or diffusion of light impingent on the surface and therefore adversely affect the crystal's performance and/or its operational lifetime. Other environmental gases, liquids and vapours can also be problematic for the same reasons. In other examples, migration of Oxygen into air from a crystal can also be problematic.

Thin, functional coatings have been utilized on optical components such as waveplates, optical crystals and lenses in order to enhance their intended performance. Existing coatings may enhance transmission over a specified wavelength range, reduce reflection, or protect the component from the outside environment. However, there is a need for an improved coating for hygroscopic crystals that are easily damaged or degraded by moisture or humidity.

An existing method of coating an optical crystal involves spin coating sol gel, in order to protect the crystal from the environment and provide an anti-reflective coating. A polymer may be dissolved in a solvent, and then dropped onto the surface of the crystal and spun off to leave a uniform layer. This sol-gel coating will deteriorate over time, for example due to exposure to light sources such as lasers and/or exposure to the environment. Further, this approach is sub-optimal because the spin coating method means that the entirety of the crystal body cannot be coated. For example, only the long sides of the crystal are coated and not the entire crystal body.

Another existing method of protecting optical crystals involves encasing the crystal in a housing, with windows at opposite ends of the housing. The housing seals the crystal from the outside environment, and may include heaters inside the housing to prevent condensation formation. However, the assembled components including the housing add weight and cost, and also make the manufacturing process more time-consuming. In some applications, the use of a housing with windows may not be appropriate as the windows may affect the wavelength of light that can be transmitted. For example, the windows may have a different wavelength-dependent transmission or reflectance profile than the crystal.

In summary, existing systems for coating hygroscopic crystals do not adequately protect hygroscopic optical crystals from water, moisture and/or humidity. This not only leads to a shorter lifetime of the optical crystal for use in a laser, but means that costly and bulky components may need to be introduced to the system to protect the crystal from the environment.

### SUMMARY

The present disclosure seeks to address these and other disadvantages encountered in the prior art by providing an improved optical apparatus comprising a coated optical crystal, and methods for coating optical crystals.

There is provided an optical apparatus comprising: a hygroscopic optical crystal; and a coating on at least a portion of the surface of the hygroscopic optical crystal, wherein the coating is non-porous and configured to prevent migration of water and/or oxygen and/or moisture therethrough.

Optionally, the surface of the hygroscopic optical crystal comprises a first face with a first normal and a second face with a second normal, the first normal is in a different orientation to the second normal, a first portion of the coating is disposed on the first face, and a second portion of the coating is disposed on the second face.

Optionally, the first portion comprises the same material and has the same structure and thickness as the second portion.

Optionally, wherein the first face and the second face meet at an edge, and wherein there is continuity of material, structure and thickness of the coating between the first portion and the second portion at the edge.

Optionally, a ratio of a coefficient of thermal expansion of the optical crystal to a coefficient of thermal expansion of the coating is in the range 1 to 9.

Optionally, the coating has a Young's Modulus is in the range 65 GPa to 410 GPa.

Optionally, a ratio of an effective refractive index of the coating and a refractive index of the optical crystal is in the range 1.36 to 2.2

Optionally, the coating is optically polarizing.

Optionally, the optical apparatus further comprises electrodes arranged on the surface of the hygroscopic optical crystal.

Optionally, the coating comprises at least one of: a dielectric material, an organic material, an oxide, a nitride, a carbide, a metal, a sulphide, a fluoride, a biomaterial, and/or a polymer.

Optionally, the coating comprises a first layer and a second layer, wherein the second layer is formed of a different material to the first layer.

There is also provided Q-switch comprising any of the optical apparatuses described herein.

There is also provided a laser comprising the Q-switch. Optionally, the laser is one of the following: dye laser, alexandrite laser with a wavelength of 755 nm, Ti:Sapphire with a wavelength of 650 nm to 1190 nm, ruby with a wavelength of 684 nm, Nd:YAG with a wavelength of 532 nm and 1064 nm, and Er:Yag with a wavelength of 2940 nm.

There is also provided a method of coating a hygroscopic optical crystal, the method comprising: providing the optical crystal in a coating chamber; introducing a first gas into the coating chamber; after introducing the first gas, evacuating the coating chamber; introducing a second gas into the coating chamber such that a coating is formed on at least a portion of a surface of the optical crystal, wherein the coating is non-porous and configured to prevent migration of water and/or oxygen and/or moisture therethrough.

Optionally, the temperature of the optical crystal is maintained below the first temperature that changes the optical/electro-optical/nonlinear optical properties permanently and/or the Curie temperature for the duration of the method.

Optionally, for the duration of the method, the temperature of the optical crystal is maintained below the lowest temperature transformation point above which the optical properties of the optical crystal irreversibly change.

Optionally, the method of claim further comprises evacuating the coating chamber, after introducing the second gas.

Optionally, the method of claim further comprises treating a portion of the surface of the optical crystal such that the coating has greater adhesion to the remaining parts of the surface, compared with the treated portion of the surface, or masking a portion of the surface of the optical crystal such that the coating is deposited on the remaining parts of the surface other than the masked portion.

Optionally, the method further comprises depositing metal electrodes on the optical crystal.

Optionally, the coating has a thickness of the order of 10-9 to 10-5 m.

Optionally, the optical crystal is pre-coated prior to the step of providing the optical crystal in a coating chamber, or prior to introducing a first gas into the coating chamber.

There is also provided an optical apparatus obtainable by providing a hygroscopic optical crystal and adding a coating to at least a portion of the hygroscopic optical crystal using atomic layer deposition, or molecular layer deposition.

Optionally, the coating is non-porous and configured to prevent migration of water and/or oxygen and/or humidity therethrough.

Optionally, adding the coating comprises: providing the optical crystal in a coating chamber; introducing a first gas into the coating chamber; after introducing the first gas, evacuating the coating chamber; introducing a second gas into the coating chamber such that the coating is formed on at least a portion of the surface of the optical crystal.

Optionally, during adding the coating, the optical crystal is maintained below the first temperature that changes the optical/electro-optical/nonlinear optical properties permanently and/or the curie temperature of the optical crystal.

Optionally, during adding the coating, the temperature of the optical crystal is maintained below the lowest temperature transformation point above which the optical properties of the optical crystal irreversibly change.

Optionally, adding the coating further comprises evacuating the coating chamber, after introducing the second gas.

### BRIEF DESCRIPTION OF THE FIGURES

Specific embodiments are now described, by way of example only, with reference to the drawings, in which:

FIG. 1a depicts a coated hygroscopic optical crystal with six faces each with a respective normal in a different orientation from the others.

FIG. 1b depicts a coated hygroscopic optical crystal with two faces each with a respective normal in a different orientations from the other.

FIG. 2 depicts a close up view of a hygroscopic optical crystal including a coating provided at an edge between two faces of the optical crystal.

FIG. 3a depicts a photograph of a hygroscopic optical crystal without any coating after 48 hours in a temperature and humidity chamber for a pre-set cycle of 85 C and 85% relative humidity.

FIG. 3b depicts a photograph of a hygroscopic optical crystal with a coating with pin-holes after 48 hours in a temperature and humidity chamber for a pre-set cycle of 85° C. and 85% relative humidity.

FIG. 4a depict a cross-section of a hygroscopic optical crystal coated with a single layer.

FIG. 4b depicts a cross-section of a hygroscopic optical crystal coated with n layers.

FIGS. 5a, 5b and 5c depict scanning electron microscope (SEM) cross-sectional images of layers of coating deposited on the surface of a material using ALD.

FIG. 6 depicts a Q-switching laser.

FIG. 7 depicts a flow chart representing a method of coating a hygroscopic optical crystal.

FIG. 8 depicts an atomic layer deposition or molecular layer deposition process.

### OVERVIEW

In overview, and without limitation, the application relates to an optical apparatus comprising a hygroscopic optical crystal and a coating on at least a portion of the hygroscopic optical crystal. The coating is non-porous and configured to prevent migration of water and/or oxygen and/or humidity through the coating.

Preferably, the coating is deposited using atomic layer deposition (ALD) or molecular layer deposition (MLD). This method is detectable in the coated hygroscopic crystal because, unlike other coating methods, the material, structure and thickness of the coating can be uniform on all faces of the crystal regardless of the direction in which the faces are oriented. Furthermore, at an edge between adjacent faces, the coating can be continuous and uniform between the faces including at the edge itself. The inventors have recognised that hygroscopic optical crystals coated using these processes have advantages over existing methods of protecting the surface of the optical crystal. For example, existing methods include providing the optical crystal in a housing with an inert gas or vacuum sealing the optical crystal in a polymer bag or package. Both of these existing methods add complexity to the manufacture and implementation of any optical apparatuses which include the optical crystal and both may limit the applications of the optical crystal due to the effect they have on the optical properties of the crystal.

The inventors have recognised that the non-porous and water/moisture resistant nature of the coating provides optimal protection against surface degradation due to humidity while also reducing the effect that this protection on the optical performance of the hygroscopic crystal.

ALD and MLD are used for many other applications but there are no known methods of using these processes to coat hygroscopic optical crystals. The inventors have recognised that these coating methods are particularly effective over other coating methods in providing thin (e.g. nanometre-thick) coatings which protect the surface of a hygroscopic optical crystal against water and/or moisture damage without damaging the surface during the coating process. Furthermore, the inventors have recognised that the ALD and MLD processes provide highly accurate control over the structure, material and thickness of the coating on the crystal, which allows greater control of the optical performance of the optical crystal when in use. Although the coating is configured to primarily protect against water and humidity, it may also be advantageous in that it protects the optical crystal from surface contamination and damage.

### DETAILED DESCRIPTION OF THE DRAWINGS

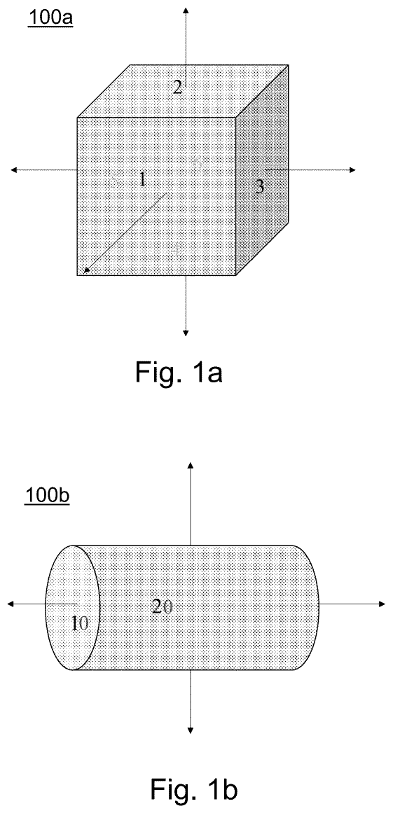

As shown in FIGS. 1a and 1b, a hygroscopic optical crystal 100a, 100b may have at least two faces. For example, the crystal may be a cube with six faces as depicted in FIG. 1a. Each arrow depicts the direction of the normal of each face. The normal of the six faces are in different orientations from one another. The normals of any two different faces will therefore be oriented in different directions. The visible faces of FIG. 1a are labelled 1, 2, and 3 and the visible faces of FIG. 1b are labelled 10 and 20.

In some implementations, the coating may be applied to all faces of the hygroscopic optical crystal. In other implementations, the coating may be only applied to some faces or a portion of the crystal including partial areas of faces. For example, a first portion of the layer can be disposed on a first face and a second portion of the layer can be disposed on a second face. The faces to be coated may be selected based on the application in which the optical crystal is to be used. For example, only the faces of the hygroscopic crystal which are used to transmit light (e.g. laser light) may be coated. Methods of masking or treating areas which are not to be coated are also described herein.

A first normal of a first face and a second normal of a second face may be oriented in different directions. In some implementations, the faces may be parallel and in different planes, with the normal of the first face being oriented 180º from the normal of the second face. Thus, in this disclosure, different directions may include a first direction and a second direction opposite to the first direction.

The optical crystal may comprise a single crystal or alternatively, it may comprise multiple crystals set parallel or in series. The optical crystal may possess parallel and/or non-parallel surfaces. It may possess flat and/or non-flat surfaces. In a particularly advantageous implementation, it may possess more than one non-flat surface to compensate for intensity induced index changes inside the crystal. It may additionally or alternatively possess a functional surface structure, such as a motheye. This functional surface structure may include the coating.

The first portion and second portion of the coating (on the first face and second face respectively) may be the same material and have the same structure and thickness as each other.

The structure, thickness and material of the coating can be detected using microscopy, for example a scanning electron microscope (SEM), to inspect a cross-section of the layer. The skilled person can ascertain that ALD or MLD has been used to coat the crystal surface due to the uniformity of thickness, structure and materials between two different portions (e.g. the aforementioned first and second portions) of the surface coating even if those portions are on different surfaces facing in different directions (e.g. the aforementioned first and second faces).

When the first face and second face of the crystal meet at an edge, a characteristic of the coatings described herein is that there will be continuity of the coating at the edge where the first portion and second portion of the coating meet. Furthermore, the coating will be uniform in thickness, structure and material over the area of the first and second portions and at the edge. For example, at the edge where faces 1 and 3 of FIG. 1a meet, the layer of coating is continuous between faces 1 and 3 including at the edge itself. Here, continuity may be understood to mean continuity of thickness, material and structure. The tolerance in uniformity of thickness may be on the scale of nanometres or angstroms.

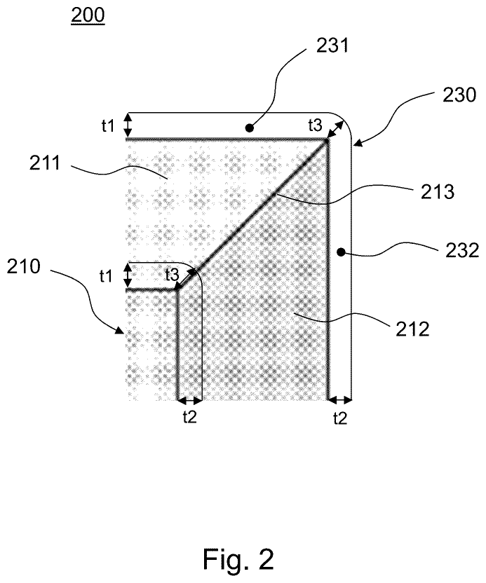

For illustrative purposes, FIG. 2 depicts a first face 211 and a second face 212 of an optical crystal 210 including a coating meeting at an edge 213. A first portion 231 and a second portion 232 of the coating 230 meet at the edge 213 of the optical crystal 210. The thickness of the coating 230 is uniform not only across the first portion 231 on the first face 211 and the second portion 232 at the second face 212, but also across the edge 213. The thickness of the coating is not only uniform across the faces and edges, but also equal across the faces and edges. In other words, the thickness t1 of the first portion 231 on the first face 211 is equal to the thickness t2 of the second portion 232 on the second face 212 and equal to the thickness t3 of the coating 230 at the edge 213.

The structure, thickness and material of the coating is uniform and equal on all surfaces irrespective of the direction in which the surfaces are oriented. In this sense, the coating has a structure, material and thickness which is independent of surface orientation. This leads to a consistent and uniform layer on the portions of the crystal to which the coating is applied. The optical and structural properties of the coated optical crystal can thus be precisely controlled. For example, applying the layer to both face 10 of FIG. 1b and the face opposing it will lead to portions of identical thickness to a nanometre (nm) or angstrom precision.

The coatings described herein may be produced using ALD or MLD. Advantageously, ALD and MLD provide a controlled method that enables the coating to be produced to an atomically specified thickness regardless of crystal surface orientation. The thickness of the coating may be of the order of 10⁻⁹ to 10⁻⁵ metres (m).

The optical crystals may be used in waveplates. Alternatively, the optical crystals may be electro-optical crystals (EO), electro-optic modulators (or Pockels cells, or Kerr cells), or NLO in frequency converters.

The crystal may comprise a number of different crystallographic point groups corresponding to point groups in three directions. A crystallographic point group is a set of symmetry operations such that each operation would leave the structure of a crystal unchanged. In other words, the same kinds of atoms would be in similar positions as before the set of operations were applied. Each point group may define a geometric crystal class.

Table 1 sets out crystal systems, their corresponding classes and corresponding examples.

TABLE 1

| System | Classes | Example |
|---|---|---|
| Orthorhombic | mm2 | BaMgF₄ |
| Tetragonal | 4 bar2 m | KDP and Isomorphs |
| Tetragonal | 4 mm | Lithium Tetraborate |
| Trigonal | 3 m | BBO |
| Hexagonal | 6 | Lithium Iodate |
| Hexagonal | 6 mm | ZnO |
| Cubic | 4 bar3 m | CuCl |

The optical crystals described herein are hygroscopic crystals. These types of optical crystals can have unique optical properties, but are susceptible to degradation. A hygroscopic crystal is one which attracts and holds water molecules and/or humidity via adsorption or absorption from the surrounding environment. A hygroscopic crystal may absorb and/or retain water/humidity/moisture and/or can become deliquescent. As an example, the hygroscopic crystals described herein may be deuterated potassium dihydrogen phosphate (DKDP) crystal.

Humidity causes the properties of a hygroscopic optical crystal to change or deteriorate. This may include optical properties, for example the transmission, reflection and polarization properties of the crystal. It may also include structural properties of the surface of the crystal. Exposure to moisture or humidity can have an immediate degradation of the crystal surface. Alternatively, the change can be more gradual if the exposure extends over a period of time at low levels. Gradual, low level deterioration can impact the operational lifetime of the optical crystal.

The hygroscopic optical crystals described herein may be grown in aqueous solution, e.g., KDP. For example, a solution growth using distilled water as a solvent may be used to grow a crystal. A detailed example of a method of producing a KDP crystal can be found in Duanyang Chen et al. (2020) Rapid Growth of a Long-seed KDP Crystal. High Power High Power Laser Science and Engineering, Vol. 8, e6. Further detailed examples can be found in Li, Zhihua & Zhang, Ran & Wu, Yaohuan & Tang, Bo & Zhang, Guochun. (2015). Controlled growth of large β-BaB 2 O 4 crystals based on theoretical guidelines. Journal of Applied Crystallography. 48; and Xin Yuan, Guangqiu Shen, Xiaoqing Wang, Dezhong Shen, Guiling Wang, Zuyan Xu, (2010) Growth and characterization of large CLBO crystals, Journal of Crystal Growth, Volume 293, Issue 1, Pages 97-101.

The skilled person will be able to determine using the common general knowledge in the field as to whether or not a crystal can be determined to be hygroscopic. Hygroscopic means the ability to adsorb or absorb water or water vapour from the surroundings. It may also by understood that in any embodiment described herein, the crystal may additionally be deliquescent, in that it may dissolve in water. The terms hygroscopic and deliquescent are a matter of objective fact based on the physical and chemical properties of the material. Objective tests for quickly determining whether or not a crystal is hygroscopic are provided herein by way of illustrative example only for the purposes of establishing a quick result and are not intended to be limiting beyond the normal meaning of hygroscopic. However, it is particularly relevant if the hygroscopic crystal undergoes a physical change leading to a difference in transmission, since this provides a more marked effect on the optical properties and performance of the crystal.

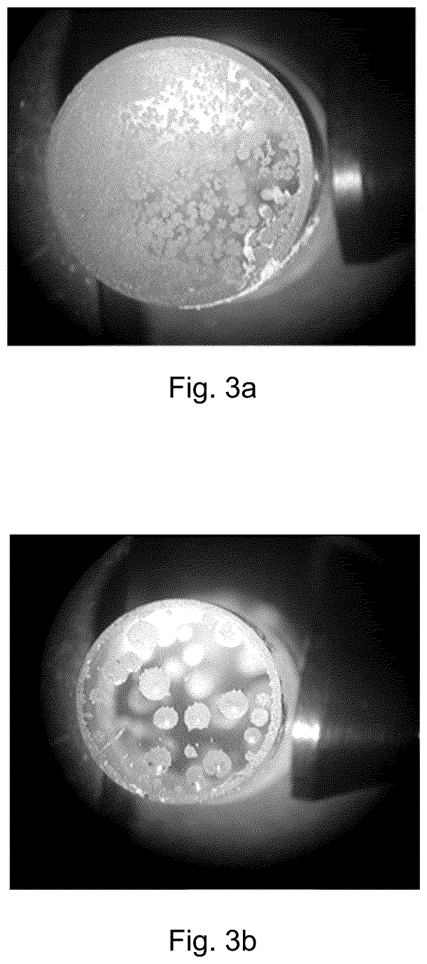

Thus, the following methods for determining whether or not a crystal is hygroscopic may be useful, but are not necessarily intended to be limiting on the definition of hygroscopic. As shown in FIG. 3a, a hygroscopic optical crystal without any coating may show signs of fogging on the surface after being exposed to humidity. In an example of a test which would indicate that the optical crystal is hygroscopic according to the present disclosure, the optical crystal may be placed in a temperature and humidity chamber for a pre-set cycle, such as 48 hours at 85° C. and 85% relative humidity. Following the cycle, and if the crystal is hygroscopic, visual inspection of the optical crystal would show the effect of the exposure to humidity. A hygroscopic crystal exposed to humidity, for example under the aforementioned test conditions, may no longer be useful for its intended optical purpose. Another method of inspection to determine if the crystal had absorbed or adsorbed water after exposure to humidity is to measure the transmission of a collimated light beam through the crystal before and after exposure to water or water vapour. A transmission reduction of, for example, >2% on average over the surface can indicate that the crystal is hygroscopic since the loss is likely to be due to scattering from changed physical properties of the crystal from absorbing or adsorbing water. Alternatively, or in addition, the power of a reflected collimated beam and/or the power of the scattered light reflected from the surface of the crystal could be used to determine if the physical properties of the crystal had changed. Other measurement or inspections of the crystal surface could be used. For example, changes mass (decrease or increase depending on the process) after such exposure in a humidity chamber could be used to determine if the crystal has absorbed or adsorbed moisture.

The coating may be non-porous, meaning that there are no pores or pin-holes in the layer that would allow water or moisture from the surrounding environment to penetrate the layer and reach the crystal surface. As shown in the example of FIG. 3b, a visual inspection of a coated crystal shows that the coating has pores or pin-holes as there are spots of humidity-affected regions that have formed on the crystal surface in spite of the presence of the coating. The fogging on the surface of the crystal has formed in areas corresponding to the location of pin-holes or pores in the coating.

The coating may be configured to allow the optical crystal to withstand 85° C. and 85% relative humidity for 48 hours without a substantial change in optical transmission of the optical crystal at the wavelength of intended use of the crystal. Inspection of the crystal using any of the methods described herein with respect to uncoated hygroscopic crystals could also be used to determine that the coating protects the crystal from water or water vapour/humidity. Such measurements would indicate that the coating prevents migration of water and/or oxygen and/or moisture. In some implementations, a substantial change in transmission or reflection (or a combination of both) using the aforementioned collimated beam inspection, for example, may be more than 0.5% change.

For some applications, for example in a Q-switch designed for a cosmetic laser, the coating may be configured to have a laser intensity damage threshold (LIDT) greater than 5 J/cm² for 10 ns at 10 Hz from 532 nm to 1064 nm, and greater than 10 J/cm² for 10 ns at 10 Hz from 1064 nm to 3000 nm.

Alternatively, or in addition, the coating may be configured to maintain a constant surface resistivity of the crystal over time.

The coating is on at least a portion of the hygroscopic optical crystal. It will be appreciated by the skilled person that a coating is distinct from a housing in that the layer is in contact with and adhered to optical crystal (for example, via an adhesion layer) whereas a housing is a separate component that is not formed or deposited on the crystal itself. Similarly, it will be appreciated that a vacuum-sealed bag around an optical crystal is not a coating since there is no adhesion of the bag to the crystal in the absence of the vacuum and the vacuum sealed bag will need to be removed to use the optical crystal for its intended purposes.

The coating being ‘formed on’ the optical crystal can here mean that the coating is directly on (i.e., in contact with) the optical crystal surface. Alternatively, ‘formed on’ or ‘disposed on’ can mean that the layer is formed on at least one intermediate layer that is in contact with the optical crystal surface. For example, in some implementations, there may be an adhesion layer between the optical crystal surface and the coating having the water- and/or moisture-resistant properties described herein and/or deposited using the methods (e.g. ALD or MLD) described herein.

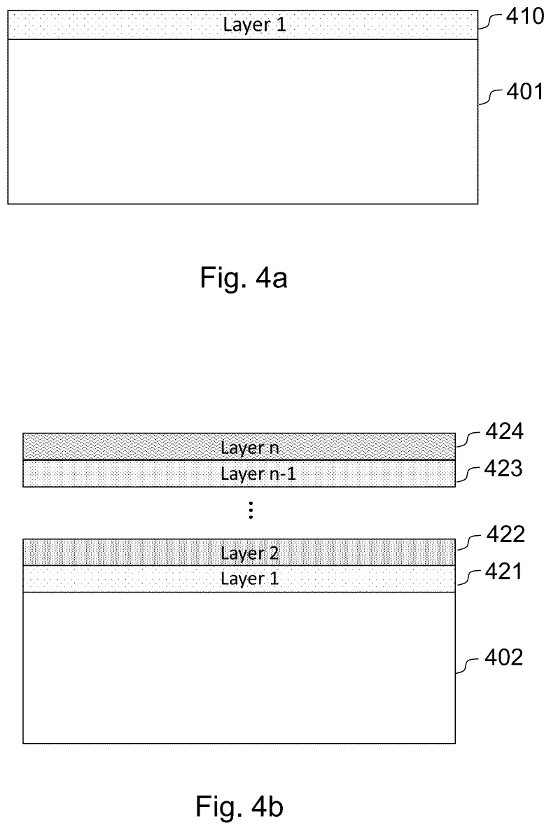

The coating may comprise a single layer, or alternatively be multi-layered. For example, FIG. 4a depicts a hygroscopic optical crystal 401 having a coating 410 with a single layer in direct contact with the surface of the optical crystal. The material of this single layer may be selected such that there is strong adhesion to the surface. In another example, FIG. 4b depicts a hygroscopic optical crystal 402 including a multi-layered coating 420. The multi-layered coating 420 comprises a first layer 421 deposited directly on the surface of the hygroscopic optical crystal and may be an adhesion layer. The multi-layered coating 420 also comprises a second layer 422 stacked on the first layer. The second layer 421 is the non-porous layer of coating having the water- and moisture-resistant properties described herein and/or deposited using the methods (e.g. ALD or MLD) described herein. The remaining layers, such as a third layer 423 and fourth layer 424 sequentially stacked on the second layer, may be further functional coatings deposited using the methods (e.g. ALD) described herein or alternatively using other methods.

In some implementations, there may be functional coating layers formed between the (water- and moisture resistant/non-porous) coating and the surface of the optical crystal and/or. In other words, the optical crystal that the coating is in contact with may itself be a (pre-)coated optical crystal. Alternatively, or in addition, functional coating layers are formed on top of the coating. The functional coating layers may be deposited by atomic layer deposition or by other deposition methods such as chemical vapor deposition or physical vapor deposition.

Physical vapor deposition technologies typically used to apply optical coatings including ion-assisted electron-beam evaporative deposition, ion beam sputtering, advanced plasma deposition, and plasma-assisted reactive magnetron sputtering.

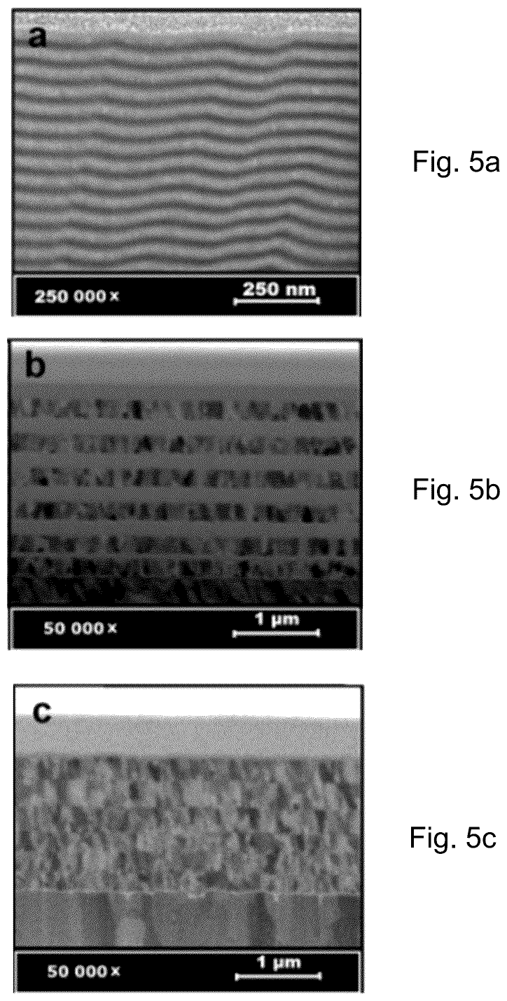

FIGS. 5a, 5b and 5c are SEM images of a cross-section of coating with more than one layer deposited by ALD. FIG. 5a is an image at 250,000 times magnification and 250 nm is shown for scale. FIGS. 5b and 5c are images at 50,000 times magnification and lum is shown for scale. Each layer can be easily identified in these figures, showing that SEM images of a cross-section of a multilayer structure deposited according to the methods described herein can indicate the presence of each of the individual layers.

Typically, thin film silicon dioxide has been used to provide an anti-reflection coating on optical crystals. Oxide coatings such as aluminium oxide or silicon dioxide (SiO₂) may be porous when applied using typical methods such as evaporating deposition, sol-gel method with spin-coating, or plasma enhanced chemical vapor deposition. Chemical vapor deposition produces thin, functional coatings, however these coatings can be porous and therefore susceptible to water and humidity permeation/penetration from the environment to the surface of the optical crystal.

When the hygroscopic optical crystal is coated using atomic layer deposition, the resulting layer of coating will be non-porous due to the inherent properties of ALD deposited layers.

The coating may be an oxide, and may be selected from one of the following oxides: Al₂O₃, CaO, CuO, Er₂O₃, Ga₂O₃, HfO₂, La₂O₃, MgO, Nb₂O₅, Sc₂O₃, SiO₂, Ta₂O₅, TiO₂, V_{X}O_{Y}, Y₂O₃, Yb₂O₃, ZnO, or ZrO₂.

Alternatively, the coating may be a nitride, and may be selected from one of the following nitrides: AlN, GaN, TaN_{X}, TiAIN, or TiN_{X}.

Alternatively, the coating may be a carbide, and may be selected from one of the following carbides: TaC, or TiC.

Alternatively, the coating may be a metal, and may be selected from one of the following metals: Ir, Pd, Pt, Ru, Au, Ag, or Al.

Alternatively, the coating may be a sulfide, and may be selected from one of the following sulfides: ZnS, or SrS.

Alternatively, the coating may be a fluoride, and may be selected from one of the following fluorides: CaF₂, LaF₃, MgF₂, or SrF₂. Fluorides have large band gaps, and fluoride coatings are particularly advantageous for hygroscopic crystals for use in deep-ultraviolet enhancement cavities.

Alternatively, the coating may be a polymer, and may be selected from one of the following polymers: PMDA-DAH, PMDA-ODA. This may be particularly advantageous in the use of crystals for biomedical applications such as drug delivery and biosensors due to their biocompatibility and wear-resistance. In some implementations, it may be advantageous for the coated optical crystal to have a bio-inert surface.

The coating may be a dielectric material, an organic material, or both or may include a combination of the two (e.g. in a dual-layer coating). It may be advantageous to apply a coating with dielectric properties in order to modify the reflective properties of the surface of the optical crystal. For example, the coating can have anti-reflecting, polarising, or optical filtering properties. This functionality may be achieved by a single layer of a coating, or by a plurality of layers of coating. The functionality may be achieved by the coating deposited by ALD alone, or may be achieved by combining the coating with other layers deposited using other coating techniques.

In an exemplary coating made up of a plurality of layers, the base layer may be aluminium doped zinc oxide (Al:ZnO) which may be deposited using atomic layer deposition onto the surface of the crystal. Subsequent layers of zirconium dioxide (ZrO₂), hafnium(IV) oxide (HfO₂), and magnesium fluoride (MgF₂) may be deposited using ALD or another deposition process such as PVD. Each of these subsequent layers may be provided to impart particular optical or structural properties. For example, magnesium fluoride may be used to impart anti-reflection properties.

The coated optical crystal may be an electro-optic modulator, such as a Pockels cell. For example, an optical apparatus including the coated optical crystal may be operated such that the polarization direction of the light is controlled by the voltage applied to it to achieve the Pockels Effect. Pockels cells may be a component in optical devices such as Q-switches for lasers and electro-optical modulators, or may also be used as sensors. In other implementations, the coated optical crystal may be a nonlinear frequency converter or a waveplate. Other types of Q-switch (whether passive or active) including the coated optical crystal are also envisaged.

Advantageously, the coating may be configured to match the thermal expansion of the optical crystal such that during temperature changes, the layer is able to deform with the optical crystal. Existing coatings such as a thin layer of SiO2 applied using IBS (Physical vapor deposition (PVD) or silicon dioxide applied using a sol-gel method by spin-coating will crack or deform during significant temperature changes.

The coefficient of thermal expansion (CTE) of the coating may be chosen to match the coefficient of thermal expansion of the uncoated optical crystal. It is particularly advantageous for the ratio of the CTE of the optical crystal to the CTE of the coating to be in the range 1 to 9.

In some implementations, there may be a plurality of layers on the optical crystal and the collective CTE of the plurality of layers forming the coating may be chosen to match the CTE of the uncoated optical crystal.

The elasticity of the coating may be chosen such that the layer does not exceed the limit of elastic deformation over the intended temperature span. If there are a plurality of layers, the elasticity may be chosen such that none of the layers forming the coating exceeds the limit of elastic deformation over the intended temperature span.

In implementations in which the coating includes a plurality of layers made from a plurality of different materials, at least one layer may be a “soft material” i.e., a more elastic layer than other layers either included in the coating or otherwise provided on the crystal. It is particularly advantageous for the coating to have a Young's Modulus is in the range 65 GPa to 410 GPa. Implementation of a more elastic layer leads to improved durability of the optical apparatus as the at least one layer can accommodate any thermal expansion mismatch. The inclusion of a more elastic layer means that other functional layers can be included to impart desirable properties even if their thermal properties would not allow for improved durability, as this function is accommodated instead by the coating having greater elasticity than the other layers.

Embodiments may include embedding polymers into the coating. In this way, the polymer can act as a (comparatively more) elastic material and can create a thermal expansion bridge between different materials. By embedding polymers, the mismatch of CTE between the crystal and the coating can be even larger. This allows for temperature fluctuation range to be larger without the coating becoming deformed or cracking.

The coating may be configured to match the refractive index of the optical crystal such that optical properties of the crystal are not affected by the coating. The layer of coating therefore acts as a protectant from moisture without affecting the passage of light into and out of the optical crystal. It is particularly advantageous for the refractive index for the coating materials to be in the range 1.36 to 2.2.

In some implementations, the refractive index may be chosen to enhance transmission, reflection or polarization properties of the optical crystal. For example, if there are a plurality of layers, the refractive index of the layers may be chosen such that there is a high refractive index differential between the different layers. For example, the ratio between refractive indices could be as high as 1.65. This allows a given optical performance to be achieved with fewer layers.

Another parameter of the coating that may be considered is the energy band gap of the material. A large band gap (e.g. above 10 eV) will allow the coating to be suitable for ultra-violet (UV) applications. For example, fluoride layers are particularly advantageous in deep-UV applications. Use of a large band gap coating can improve the durability of the optical apparatus. If the photon entering the layer of coating has an energy that is larger than the band gap, it will be absorbed leading to faster degradation of the coating.

The refractive index of the coating may be chosen to achieve anti-reflection. It would be appreciated by the skilled person that if the refractive index of the coating is the square root of the refractive index of the optical crystal, then when the wavelength in the coating is four times the thickness of the coating, there will be theoretically zero reflectance. This leads to anti-reflection when the coated optical crystal is in air.

For example, a first layer of Al₂O₃ may be deposited onto the optical crystal, with an optical thickness that is a quarter of the wavelength. A further layer of Ta₂O₅ may be deposited with an optical thickness that is a half of the wavelength. A further layer of MgF₂ may be deposited with an optical thickness that is a quarter of the wavelength. This three-layer coating achieves high transmission and reduces reflection.

Alternatively, the refractive index may be chosen to increase reflectivity and minimise transmission.

In some implementations, the coating may be optically polarizing.

In some implementations, there is provided a Q-switch comprising any of the coated optical crystals described herein. In some implementations, there is provided a laser comprising a Q-switch of this kind.

For example, the laser may be used in cosmetic applications such as tattoo removal, laser resurfacing treatments, and hair removal. Longevity of these crystals in such applications is important, and it is advantageous that a crystal does not significantly degrade as a result of the environment or through repeated use of the laser. Thus, the water/humidity resistance and the high laser induced damage threshold of the coating are important properties in applications of this kind.

Q-switched lasers comprise a variable attenuator inside the optical resonator. During operation of a Q-Switch laser, the laser medium will be pumped, storing energy in the gain medium. After a given time period, the medium will be gain saturated. The Q-switch can then be changed from low Q factor to high Q factor. This leads to the optical amplification by stimulated emission, and the energy stored in the laser medium is quickly depleted. This process leads to a short pulse of light output from the laser, which may have a high peak intensity. This type of laser is useful in applications such as tattoo removal, which requires high laser intensity in picosecond-nanosecond pulses to break down ink pigments in the skin.

One example of a Q-Switch laser is Nd:YAG operating at a wavelength and 1064 nm that can be frequency doubled to 532 nm.

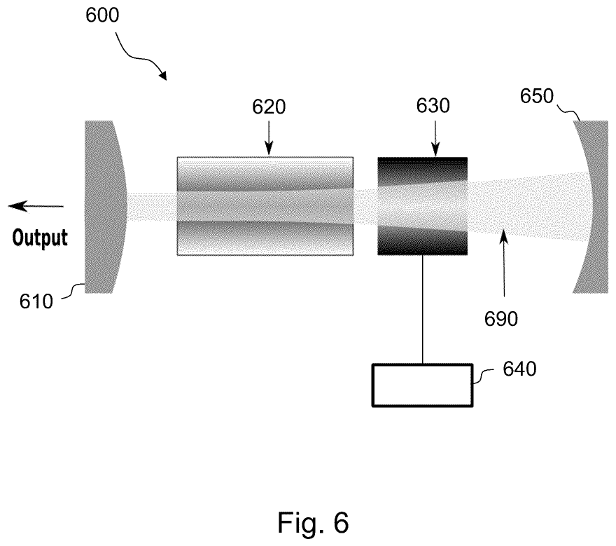

FIG. 6 depicts a laser system 600 according to an embodiment comprising an output coupler 610, a laser crystal 620 (which can also be a gas or a semiconductor material), a Q-switch 630, a polarizer (not shown) a mirror 650 and a Pockels cell driver 640. The output coupler 610 may be a semi-transparent dielectric mirror and it, along with the mirror 650 may define an optical resonator 690 of a laser. The laser crystal 620 may be any suitable laser (gain) medium, which may be pumped by a pump source. The Q-switch 630 is any of the coated hygroscopic optical crystals described herein. The Pockels cell driver 640 may provide high voltage pulses to the Q-switch (coated optical crystal) functioning as a Pockels Cell. It would be appreciated by the skilled person that the Q-switch functionality may alternatively be achieved in other ways but still with a coated hygroscopic optical crystal as defined herein.

It will be understood that the above description of specific embodiments is by way of example only and is not intended to limit the scope of the present disclosure. Many modifications of the described embodiments, some of which are now described, are envisaged and intended to be within the scope of the present disclosure.

Any of the (e.g. ALD, MLD) coated hygroscopic optical crystals described herein may be implemented into laser systems such as Q-switches, optical amplifiers, and non-linear wavelength conversions in pulsed or continuous wave (CW) lasers.

The laser may be one of: a solid-state laser, a gas laser, an excimer laser, a dye laser or a semiconductor laser. It would be appreciated by the skilled person that different dyes have different emission spectra, allowing dye lasers to cover a broad wavelength range from about 320 nm to 1500 nm. Further examples of lasers include alexandrite with a wavelength of 755 nm, Ti:Sapphire with a wavelength of 650 nm to 1190 nm, ruby with a wavelength of 684 nm, Nd:YAG with a wavelength of 532 nm and 1064 nm, Er:Yag with a wavelength of 2940 nm. These wavelengths are the primary emission wavelengths of the laser.

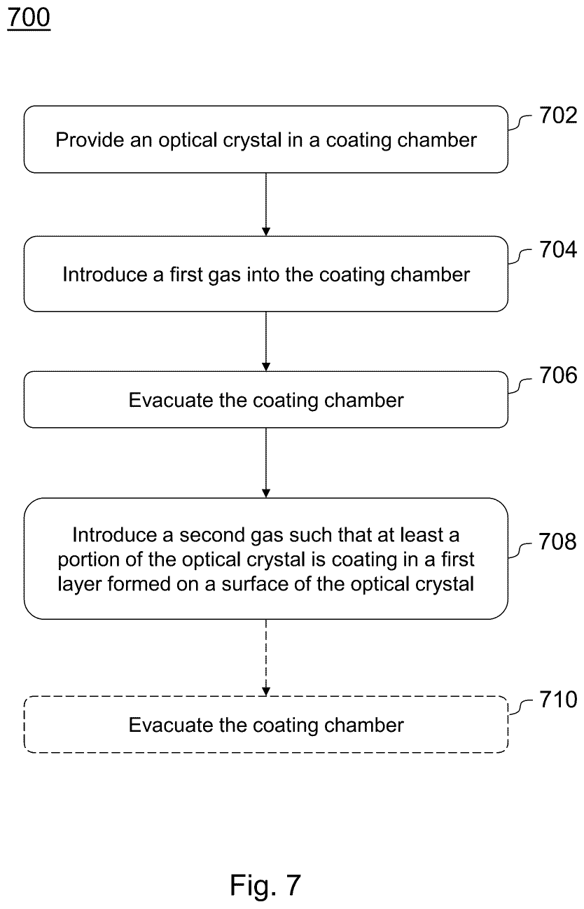

FIG. 7 depicts method 700 for coating a hygroscopic optical crystal with ALD or MLD according to the present disclosure.

At step 702, the optical crystal is provided in a coating chamber. The coating chamber may be a vacuum chamber.

At step 704, a first gas in introduced into the coating chamber. For example, the first gas may be. The first gas may also be referred to as a first precursor gas or first reactant gas. This step may be referred to as the first half-cycle.

At step 706, the coating chamber is evacuated. This step may be referred to as a first purge. The residual first gas and any reaction products are removed from the coating chamber in this step.

At step 708, the second gas is introduced into the coating chamber, such that at least a portion of the optical crystal is coated in a first layer on a surface of the optical crystal. According to the present disclosure, the coating is non-porous and configured to prevent migration of water and/or oxygen and/or moisture therethrough. The second gas may also be referred to as a second precursor gas or a second reactant gas. This step may be referred to as the second half-cycle.

Optionally, the method may further comprise evacuating the coating chamber at step 710. As at step 706, this may be referred to as a purge during which the residual gas precursor and any reaction products may be removed from the coating chamber.

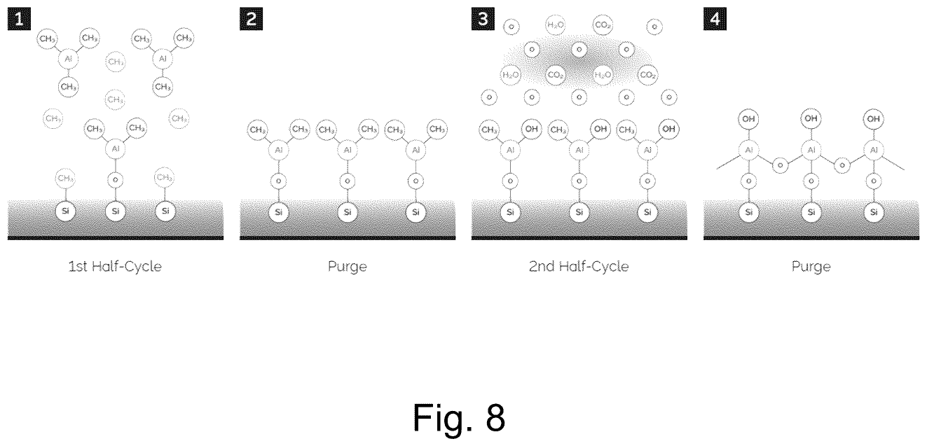

The second gas is introduced sequentially, without overlap with the first gas. As depicted in FIG. 8, each gas may react with reactive sites on the surface until all of the sites have been occupied. The coating chamber may be evacuated only once the reaction of the second gas with the layer deposited by the first gas has finished and all reactive sites have been occupied. During the purge, the by-products of the reaction are removed.

Atomic layer deposition (ALD) allows for ultra-thin films of a few nanometres as it deposits a single atomic or molecular layer in each cycle, allowing the thickness and composition of the films can be controlled at the atomic or molecular level. Cycles may be repeated to build up layers of the desired thickness and or to add more than one layer to the surface to create a multilayer stack as shown in FIG. 4b.

The reaction mechanism may depend on the particular ALD process and the particular gases used.

In some implementations, plasma enhanced ALD (PE-ALD) may be used to coat the optical crystal at lower temperatures, for example. In an example of an application which is not related to coating optical crystals, PE-ALD has been used to deposit Al₂O₃ film onto high aspect ratio features dry-etched into HgCdTe, as described in Richard Fu, James Pattison, “Advanced thin conformal Al2O3 films for high aspect ratio mercury cadmium telluride sensors,” Opt. Eng. 51(10) 104003 (2012)”.

Optionally, the method 700 is performed at a temperature below the first transformation point (i.e. the lowest temperature transformation point) where the crystal irreversibly changes optical properties. This may be performed using PE-ALD, but embodiments are not necessarily limited thereto. For some crystals, the method is therefore performed at or below 150° C. In some implementations, the first gas and/or the second gas may be introduced when the temperature. At temperatures higher than the first transition point, the properties of the optical crystal will be affected.

In some implementations, a portion of the surface of the optical crystal may be treated or masked, such that the first layer adheres to the remaining parts of the surface, other than the treated portion of the surface. In such a masking process, the surface is treated so that the layer does not form on the treated portion, or otherwise the treatment facilitates ease of removal of the layer from the treated portion, for example by preventing (or minimising) adhesion of the layer to the treated portion.

Metal electrodes may be deposited before or after the ALD process. In some implementations, they may be deposited on or around the portions of the surface that have been treated or masked. Such electrodes are configured to apply a supplied current or voltage to parts of the crystal in order to control the crystal states in real time for applications such as Q-switching.

It is to be understood that the above description is intended to be illustrative, and not restrictive. Many other implementations will be apparent to those of skill in the art upon reading and understanding the above description. Although the present disclosure has been described with reference to specific example implementations, it will be recognized that the disclosure is not limited to the implementations described, but can be practiced with modification and alteration within the scope of the appended claims. Accordingly, the specification and drawings are to be regarded in an illustrative sense rather than a restrictive sense.

1. An optical apparatus comprising:
a hygroscopic optical crystal; and
a coating on at least a portion of a surface of the hygroscopic optical crystal, wherein the coating is non-porous and configured to prevent migration of water and/or oxygen and/or moisture therethrough.

2. The optical apparatus according to claim 1, wherein the surface of the hygroscopic optical crystal comprises a first face with a first normal and a second face with a second normal,
the first normal is in a different orientation to the second normal,
a first portion of the coating is disposed on the first face, and
a second portion of the coating is disposed on the second face.

3. The optical apparatus according to claim 2, wherein the first portion comprises the same material and has the same structure and thickness as the second portion.

4. The optical apparatus according to claim 2, wherein the first face and the second face meet at an edge, and wherein there is continuity of material, structure and thickness of the coating between the first portion and the second portion at the edge.

5. The optical apparatus according to claim 1, wherein a ratio of a coefficient of thermal expansion of the optical crystal to a coefficient of thermal expansion of the coating is in a range 1 to 9.

6. The optical apparatus according to claim 1, wherein the coating has a Young's Modulus is in a range 65 GPa to 410 GPa.

7. The optical apparatus according to claim 1, wherein a ratio of an effective refractive index of the coating and a refractive index of the optical crystal is in a range 1.36 to 2.2.

8. The optical apparatus according to claim 1, wherein the coating is optically polarizing.

9. The optical apparatus according to claim 1, further comprising electrodes arranged on the surface of the hygroscopic optical crystal.

10. The optical apparatus according to claim 1, wherein the coating comprises at least one of: a dielectric material, an organic material, an oxide, a nitride, a carbide, a metal, a sulphide, a fluoride, a biomaterial, and/or a polymer.

11. The optical apparatus according to claim 1, wherein the coating comprises a first layer and a second layer, wherein the second layer is formed of a different material to the first layer.

12. A Q-switch comprising the optical apparatus of claim 1.

13. A laser comprising the Q-switch of claim 12, optionally wherein the laser is one of the following: dye laser, alexandrite laser with a wavelength of 755 nm, Ti:Sapphire with a wavelength of 650 nm to 1190 nm, ruby with a wavelength of 684 nm, Nd:YAG with a wavelength of 532 nm and 1064 nm, and Er:Yag with a wavelength of 2940 nm.

14. A method of coating a hygroscopic optical crystal, the method comprising:
providing the optical crystal in a coating chamber;
introducing a first gas into the coating chamber;
after introducing the first gas, evacuating the coating chamber; and
introducing a second gas into the coating chamber such that a coating is formed on at least a portion of a surface of the optical crystal, wherein the coating is non-porous and configured to prevent migration of water and/or oxygen and/or moisture therethrough.

15. The method of claim 14, wherein, for the duration of the method, a temperature of the optical crystal is maintained below the lowest temperature transformation point above which optical properties of the optical crystal irreversibly change.

16. The method of claim 14, further comprising, after introducing the second gas, evacuating the coating chamber.

17. The method of claim 14, further comprising treating a portion of the surface of the optical crystal such that the coating has greater adhesion to the remaining parts of the surface, compared with the treated portion of the surface, or
masking a portion of the surface of the optical crystal such that the coating is deposited on the remaining parts of the surface other than the masked portion.

18. The method of claim 14, further comprising depositing metal electrodes on the optical crystal.

19. The method of claim 14, wherein the coating has a thickness of an order of 10⁻⁹ to 10⁻⁵ m.

20. The method of claim 14, wherein the optical crystal is pre-coated prior to the step of providing the optical crystal in a coating chamber, or prior to introducing a first gas into the coating chamber.

21. An optical apparatus obtainable by providing a hygroscopic optical crystal and adding a coating to at least a portion of the hygroscopic optical crystal using atomic layer deposition, or molecular layer deposition.

22. The optical apparatus according to claim 21, wherein the coating is non-porous and configured to prevent migration of water and/or oxygen and/or humidity therethrough.

23. The optical apparatus according to claim 21, wherein adding the coating comprises:
providing the optical crystal in a coating chamber;
introducing a first gas into the coating chamber;
after introducing the first gas, evacuating the coating chamber; and
introducing a second gas into the coating chamber such that the coating is formed on at least a portion of a surface of the optical crystal.

24. The optical apparatus according to claim 23, wherein during adding the coating, a temperature of the optical crystal is maintained below the lowest temperature transformation point above which optical properties of the optical crystal irreversibly change.

25. The optical apparatus according to claim 23, wherein, after introducing the second gas, adding the coating further comprises evacuating the coating chamber.
